(19) United States
(12) Patent Application Publication
(10) Pub. No.: US 2025/0377794 A1
(43) Pub. Date: Dec. 11, 2025

(54) READ OPERATION WITH BOOST MODULATION IN MEMORY DEVICES

(71) Applicant: Micron Technology, Inc., Boise, ID (US)

(72) Inventors: Go Shikata, San Jose, CA (US); Kitae Park, Cupertino, CA (US)

(21) Appl. No.: 19/223,740

(22) Filed: May 30, 2025

Related U.S. Application Data
(60) Provisional application No. 63/657,323, filed on Jun. 7, 2024.

(51) Int. Cl. G06F 3/06; G11C 16/04; G11C 16/26; G11C 16/30

(52) U.S. Cl. CPC G06F 3/0611; G06F 3/0659; G06F 3/0679; G11C 16/0483; G11C 16/26; G11C 16/30

(57) ABSTRACT

An example system includes a memory device and a processing device operatively coupled to the memory device. The processing device is configured to: produce a first data item by performing, using a first boost voltage level, a first read strobe with respect to a set of memory cells storing encoded data item; apply an offset to the first boost voltage level to produce a second boost voltage level; produce a second data item by performing, using the second boost voltage level, a second read strobe with respect to the set of memory cells; and produce, based on the first data item and the second data item, decoded data item corresponding to the encoded data item.

### REFERENCE TO RELATED APPLICATION

This application claims the priority benefit of U.S. Provisional Patent Application No. 63/657,323, filed Jun. 7, 2024, the entirety of which is incorporated herein by reference.

### TECHNICAL FIELD

Implementations of the disclosure are generally related to memory sub-systems, and more specifically, relate to performing read operations with boost modulation in memory devices.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of some implementations of the disclosure.

FIG. 1A illustrates an example computing system that includes a memory sub-system in accordance with some implementations.

FIG. 1B is a block diagram of a memory device in communication with a memory sub-system controller of a memory sub-system according to an implementation.

FIG. 2A-2B are schematics of portions of an array of memory cells as could be used in a memory of the type described with reference to FIG. 1B according to an implementation.

FIG. 3 is schematically illustrates threshold voltage distributions of multiple memory cells of a memory array according to an implementation.

FIG. 4 is a conceptual depiction of a threshold voltage distribution of multiple memory cells at one stage following programming for use with various implementations.

FIG. 5 schematically illustrates a simplified component diagram of a sense circuit operating in accordance with some aspects of the present disclosure.

FIG. 6 schematically illustrates possible read level positions with respect to the threshold voltage distributions, as well as corresponding “hard” and “soft” information bits, in accordance with aspects of the present disclosure.

FIG. 7 schematically illustrates a set of graphs illustrating the boost modulation for performing a read operation, in accordance with aspects of the present disclosure.

FIG. 8 is a high-level flow diagram of an example method of performing a read operation with boost modulation in a memory device, in accordance with aspects of the present disclosure.

FIG. 9 is a block diagram of an example computer system in which implementations of the present disclosure can operate.

### DETAILED DESCRIPTION

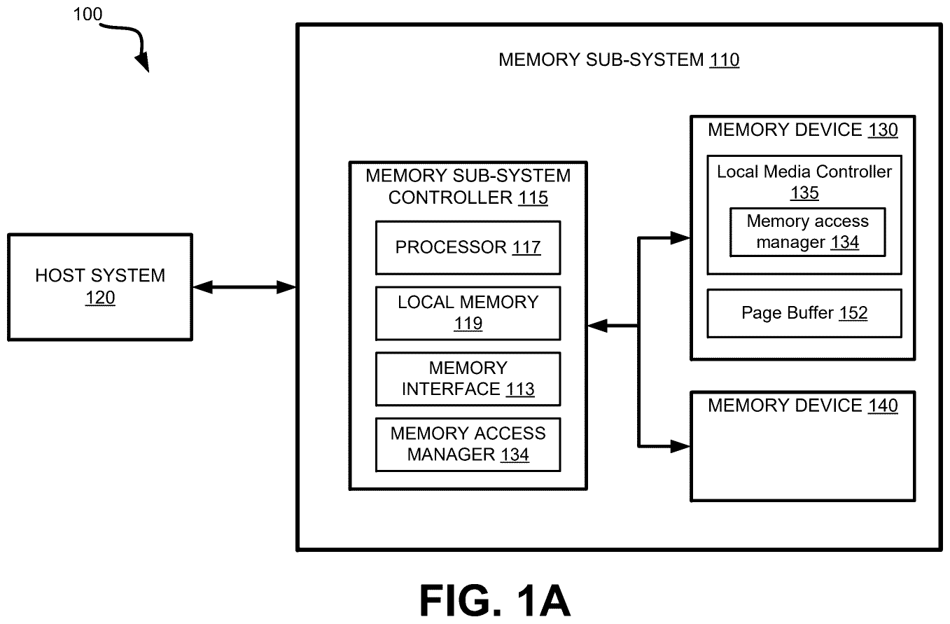

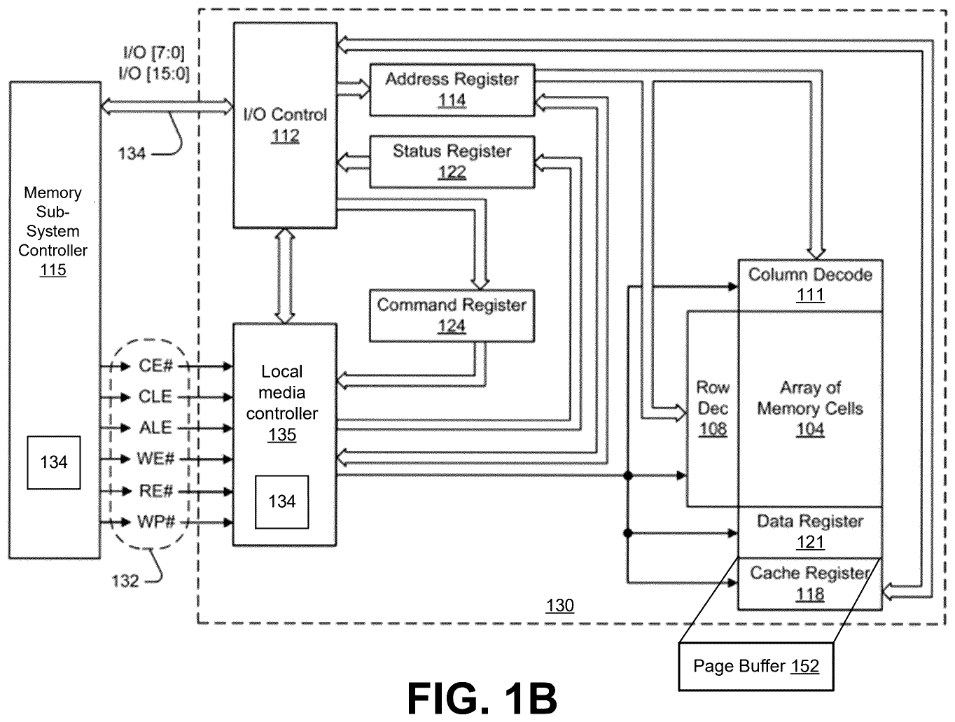

Implementations of the present disclosure are directed to performing read operations with boost modulation in memory devices. A memory sub-system may be a storage device, a memory module, or a combination of a storage device and memory module. Examples of storage devices and memory modules are described below in conjunction with FIG. 1. In general, a host system may utilize a memory sub-system that includes one or more components, such as memory devices that store data. The host system may provide data to be stored at the memory sub-system and may request data to be retrieved from the memory sub-system.

A memory sub-system may utilize one or more memory devices, including any combination of the different types of non-volatile memory devices and/or volatile memory devices, to store the data provided by the host system. In some implementations, a memory sub-system may be represented by a solid-state drive (SSD), which may include one or more non-volatile memory devices. In some implementations, the non-volatile memory devices may be provided by negative-and (NAND) type flash memory devices. Other examples of non-volatile memory devices are described below in conjunction with FIG. 1. A non-volatile memory device is a package of one or more dice. Each die may include one or more planes. A plane is a portion of a memory device that includes multiple memory cells. Some memory devices may include two or more planes. For some types of non-volatile memory devices (e.g., NAND devices), each plane includes a set of physical blocks. Each block includes a set of pages. “Block” herein shall refer to a set of contiguous or non-contiguous memory pages. A “block” may refer to a unit of the memory device used to store data and may include a group of memory cells. An example of a “block” is an “erasable block,” which is the minimal erasable unit of memory, while “page” is a minimal writable unit of memory. Each page includes a set of memory cells.

A memory device may include multiple memory cells arranged in a two-dimensional grid. The memory cells are formed onto a silicon wafer in an array of columns and rows. A memory cell includes a capacitor that holds an electric charge and a transistor that acts as a switch controlling access to the capacitor. Accordingly, the memory cell may be programmed (written to) by applying a certain voltage, which results in an electric charge being held by the capacitor. The memory cells are joined by wordlines, which are conducting lines electrically connected to the control gates of the memory cells, and bitlines, which are conducting lines electrically connected to the drain electrodes of the memory cells.

Depending on the cell type, each memory cell may store one or more bits of binary information and has various logic states that correlate to the number of bits being stored. The logic states may be represented by binary values, such as “0” and “1”, or combinations of such values. A memory cell may be programmed (written to) by applying a certain voltage to the memory cell, which results in an electric charge being held by the memory cell, thus allowing modulation of the voltage distributions produced by the memory cell. A set of memory cells referred to as a memory page may be programmed together in a single operation, e.g., by selecting consecutive bitlines.

Precisely controlling the amount of the electric charge stored by the memory cell allows establishing multiple logical levels, thus effectively allowing a single memory cell to store multiple bits of information. A read operation may be performed by comparing the measured threshold voltages (Vₜ) exhibited by the memory cell to one or more reference voltage levels in order to distinguish between two logical levels for single-level cell (SLCs) and between multiple logical levels for multi-level cells. Each logical level may be translated into a corresponding binary representation of the content of the memory cell. In an illustrative example, a Gray code may be employed for translating the cell charge levels (voltage levels) into their respective binary representations and vice versa. A Gray code refers to an encoding in which adjacent numbers have a single digit different by one.

Memory access operations (e.g., a read operation, a programming (write) operation, an erase operation, etc.) may be executed with respect to sets of the memory cells, e.g., in response to receiving memory access commands from the host. A memory access operation may specify the requested memory access operation (e.g., write, erase, read, etc.) and a logical address, which the memory sub-system would translate to a physical address identifying a set of memory cells (e.g., a block).

In order to improve endurance of a memory device, the data to be written to the memory device may be modulated to achieve a desired distribution of the charge levels in the memory cells addressable by a given wordline and, in some implementations, also in the memory cells addressable by neighboring wordlines of the given wordline. For example, a random data pattern encoded by a Gray code would result in uniform distribution of the memory cell charge levels (such that the number of memory cells at an arbitrary chosen charge level being roughly equal to the number of memory cells at any other charge level).

The modulated data may be encoded prior to being stored on a memory device, and thus would need to be decoded when later retrieved from the memory sub-system. For example, a sequence of symbols (e.g., representing one or more bits of binary information), may be transformed by an encoder to generate a codeword, which may then be stored on a memory device. However, in some cases, the sensed data read back from the memory device may differ from the original encoded data, e.g., on account of errors (e.g., bit-flip errors) that may have occurred during storage and/or retrieval of the encoded data to/from the memory device.

In some implementations, the data may be encoded using an error correcting code (ECC), which produces encoded data that includes redundant information allowing the original data to be recovered even if some errors have been introduced during the data storage and/or retrieval. Accordingly, the transformation employed by the encoder may be chosen such that the errors (e.g., bit flips that may occur when storing and/or retrieving the codeword) may be detected and corrected when the codeword is later retrieved from the memory device thereof.

One class of ECCs that may be used are linear codes, which may be characterized by a set of linearly independent relationships. For example, a linear code having codewords of length N, that may carry K information symbols and (N-K) (or M) parity-check symbols, in general, may be characterized by (N-K) linear relationships. Linear codes may be defined by a parity-check matrix, which may describe the linear relationships that elements of a valid codeword must satisfy. Each row of a parity-check matrix, for example, may describe a separate linear relationship that a valid codeword must satisfy (e.g., requiring the weighted sum of specific elements of the codeword to equal zero), with the value in each column indicating a weight that a particular element is given in the relationship. For instance, each row of a parity-check matrix that defines a binary linear code may require the modulo-2 sum of specific bits of a codeword, which may be given a column weight of ‘1’ (and all other bits ‘0’), to be equal to zero.

Low Density Parity Check (LDPC) codes are a family of linear codes having sparsely populated parity-check matrices (e.g., having a low density of non-zero symbols). A binary LDPC code having codewords of length N, comprising K bits of information and M parity-check bits, may be defined by a parity-check matrix of size M×N. Similarly, a non-binary LDPC code, in which each symbol of the non-binary alphabet represents s bits, may be defined by a parity-check matrix of size sM×sN.

A parity-check matrix having M rows and N columns may define an LDPC code having codewords of length N that may carry K information bits and M parity bits. Each row of the parity-check matrix may describe a linear relationship that a valid codeword of the LDPC code must satisfy. For example, a row of the parity-check matrix may require a valid codeword to satisfy the relationship: bit-2⊕bit-6⊕bit-7⊕ . . . ⊕bit-N-4-=0.

Data encoded using a chosen coding scheme (e.g., as a Low Density Parity Check (LDPC)) code may be decoded using different techniques, which may vary in terms of the input they take and the error correction capabilities they provide. Hard-decision decoding techniques, for example, may rely on a “hard” input value of a received codeword (e.g., a singular determination as to whether each bit-value of a codeword is ‘0’ or ‘1’). A memory sub-system, for example, in retrieving a stored codeword from a memory device, may perform a read operation that makes a hard decision as to the value of each bit of the codeword (i.e., as being either ‘0’ or ‘1’) and returns a series of “hard bits.”

Should the decoder fail to correct one or more errors in the sensed data, the memory sub-system may perform a read error handling sequence in an attempt to recover the data. The read error handling sequence may include one or more read error handling operations. An error handling operation, for example, may include one or more read retries using different parameters, such as the read voltage, as compared to the previous read operation performed on the memory cell. In some implementations, read voltage level adjustments may be performed based on values of one or more data state metrics obtained from a sequence of read and/or write operations. In an illustrative example, the data state metric may be represented by a raw bit error rate (RBER), which refers to the error rate in terms of a measure of bits that contain incorrect data (i.e., bits that were sensed erroneously) when a data access operation is performed on a memory device (e.g., the ratio of the number of erroneous bits to the number of all data bits stored in a certain portion, such as a specified block, of the memory device).

In some implementations, upon failing to successfully decode the sensed data based on the hard bits, the memory sub-system may employ a soft-decision decoding techniques, which may take into account “soft” input information (alongside a hard input value) indicating the reliability of a hard value determination (e.g., a confidence level or likelihood that a particular bit-value is in fact ‘0’ or ‘1’). Thus, a memory sub-system, in retrieving a stored codeword, may perform a read operation that not only returns a hard value as a series of hard bits, but also a series of one or more “soft bits” for each hard bit, which may indicate a reliability of a particular hard bit determination.

A read operation may measure the threshold voltage of a target memory cell of a set of memory cells. By comparing the measured threshold voltage value to the estimated threshold voltage distributions associated with the set of memory cells, the read operation may return a predefined number of “soft bits” of information for each “hard” bit. Soft-decision decoding techniques may be described in terms of the number of hard bits (H) and soft bits (S) that are provided as input to the decoder (e.g., 1H2S, 1H3S, etc.).

In general, soft-decision decoding techniques may provide for relatively better error correction as compared to hard-decision decoding techniques, but they tend to be more expensive to implement. Soft-decision decoding techniques, for example, may involve more complicated and time-consuming read operations (e.g., to obtain the desired reliability information), utilize higher power and/or more complex decoding circuitry, or present other issues.

In an illustrative example, a memory sub-system may perform a read operation that returns an estimated threshold voltage value for a particular memory cell. The voltage value may fall within one of a predefined plurality of decoder input bins. Each decoder input bin may be associated with a predefined sequence of bit values, including one hard bit value and one or more soft bit values. For example, the memory sub-system may perform a read operation that returns three soft bits of information for each hard bit, with ‘000’ indicating the lowest level of reliability and ‘111’ indicating the highest level of reliability in the hard bit determination.

The combination of the hard bit and the soft bits may be converted into a likelihood value, which reflects the probability that the memory cell will be decoded as a specific binary value (e.g., “1”). In other words, the combination of the hard bit and one or more corresponding soft bits may be translated into a likelihood value that reflects the probability of the memory cell (having its threshold voltage within a decoder input bin that is identified by the combination of the hard bit and the corresponding soft bits) to be decoded as a particular binary value (e.g., “1”).

In some implementations, the likelihood value may be represented by the log likelihood ratio:

$$LLR ( bit i ) = log ( \frac{P ( bit i = 0 \vert read info}{P ( bit i = 1 \vert read info} )$$

where i is the identifier of the bit (the memory cell for SLC),
read info is the information read from the memory device (i.e., the combination of the hard bit and its corresponding soft bits),
P(bit i=0|read info) is the probability of bit i be decoded as 0 based on the information read from the memory device (i.e., the combination of the hard bit and its corresponding soft bits), and
P bit i=1|read info) is the probability of bit i be decoded as 1 based on the information read from the memory device (i.e., the combination of the hard bit and its corresponding soft bits).

In some implementations, converting the combination of the hard bit and the soft bits into a corresponding likelihood (e.g., the log likelihood ratio (LLR)) value may be performed using a look-up table (LUT), which may map various possible combinations of the hard bit and soft bits into corresponding LLR values. The LUT may be pre-computed by the manufacturer of the memory sub-system and stored in the metadata area of a memory device. The controller may then provide the LLR values corresponding to the sensed data returned by a read operation to an LDPC decoder, which may attempt to decode the sensed data.

In an illustrative example, the controller may perform a read operation returning one “hard” bit and one “soft” bit of information (1H1S), which would involve three read strobes: a strobe at the base read level to produce the “hard” bit,” and two strobes with small negative and positive offsets applied to the read level, to produce the “soft” bit. The offsets are selected in such a way that the respective read levels produced by applying the offsets to the base read level would fall within the intersection of the two neighboring voltage distributions. Evidently, performing three read strobes in course of a single read operation results in tripling the latency of the read operation.

Aspects of the present disclosure address the above-noted and other deficiencies by performing only one additional read strobe for every read operation, which would result in half-bit “soft” data as compared to one “soft” bit requiring two additional read strobes.

As the shift of the threshold voltage level may be caused by either charge loss (e.g., due to electrons escaping from the floating gate) or charge gain (e.g., due to the read disturb). Accordingly, if one of the two processes prevail, only one additional read strobe may be sufficient in order to produce an accurate read result.

During the read operation, depending upon the position of the target cell relative to the corresponding threshold voltage (Vₜ) distribution, which is determined by comparing the discharge current (I_{cell}) to the read level, the boost level may be adjusted either upwards or downwards in order to capture the corresponding ½ “soft” bit of information. Accordingly, responsive to performing the strobe at the target read level, thus acquiring the “hard” bit of information, the controller may proceed to acquire the ½ bits of “soft” information, by performing the strobe at either the high target level or the low target level, as described in more detail herein below. The controller may then provide the LLR values corresponding to the sensed data returned by the two-strobe read operation to an LDPC decoder, which may attempt to decode the sensed data.

Therefore, advantages of the systems and methods implemented in accordance with some implementations of the present disclosure include reducing the read operation latency, as described in more detail herein below.

FIG. 1A illustrates an example computing system 100 that includes a memory sub-system 110 in accordance with some implementations of the present disclosure. The memory sub-system 110 can include media, such as one or more volatile memory devices (e.g., memory device 140), one or more non-volatile memory devices (e.g., memory device 130), or a combination of such media or memory devices.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some implementations, the host system 120 is coupled to multiple memory sub-systems 110 of different types. FIG. 1A illustrates one example of a host system 120 coupled to one memory sub-system 110. The host system 120 can provide data to be stored at the memory sub-system 110 and can request data to be retrieved from the memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple-level cells (TLCs), quad-level cells (QLCs), and penta-level cells (PLCs) can store multiple bits per cell. In some implementations, each of the memory devices 130 can include one or more arrays of memory cells such as SLCs, MLCs, TLCs, QLCs, PLCs or any combination of such. In some implementations, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (“controller 115”) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some implementations, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another implementation of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some implementations, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some implementations, the memory devices 130 include local media controllers 135 that operate in conjunction with memory sub-system controller 115 to execute operations on one or more memory cells of the memory devices 130. An external controller (e.g., memory sub-system controller 115) can externally manage a memory device 130 (e.g., perform media management operations on the memory device 130). In some implementations, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

In some implementations, the memory sub-system 110 includes a memory interface component 113. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. For example, the memory sub-system controller 115 can include a processor 117 (processing device) configured to execute instructions stored in local memory 119 for performing the operations described herein.

In some implementations, memory sub-system 110 includes a memory access manager 134 configured to carry out memory access operations, e.g., in response to receiving memory access commands from the host system 120. In some implementations, the memory access manager is implemented by the memory sub-system 110 using firmware and/or hardware components. In some implementations, the memory access manager 134 may be implemented by the memory sub-system controller 115 and/or local media controller 135. In an illustrative example, the memory access manager 134 receives, from a requestor, such as memory interface 113, a request to read a data page of the memory device 130. A read operation can include a series of read strobes, such that each strobe applies a certain read level voltage to a chosen wordline of a memory device 130 in order to compare the estimated threshold voltages V, of a set of memory cells to one or more read levels corresponding to the expected positions of the voltage distributions of the memory cells.

In some implementations, the memory device 130 includes a page buffer 152, which contains the circuitry used to program data to the memory cells of the memory device 130 and to read the data out of the memory cells.

FIG. 1B is a simplified block diagram of a first apparatus, in the form of a memory device 130, in communication with a second apparatus, in the form of a memory sub-system controller 115 of a memory sub-system (e.g., the memory sub-system 110 of FIG. 1A), according to an implementation. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

The memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line can be associated with more than one logical row of memory cells and a single data line can be associated with more than one logical column. Memory cells (not shown in FIG. 1B) of at least a portion of the array of memory cells 104 are capable of being programmed to one of at least two target data states.

Row decode circuitry 108 and column decode circuitry 111 are provided to decode address signals. Address signals are received and decoded to access the array of memory cells 104. The memory device 130 also includes input/output (I/O) control circuitry 112 to manage input of commands, addresses and data to the memory device 130 as well as output of data and status information from the memory device 130. An address register 114 is in communication with the I/O control circuitry 112 and row decode circuitry 108 and column decode circuitry 111 to latch the address signals prior to decoding. A command register 124 is in communication with the I/O control circuitry 112 and local media controller 135 to latch incoming commands.

The local media controller 135 controls access operations to the array of memory cells 104 in response to the commands and generates status information for the external memory sub-system controller 115. The local media controller 135 controls the row decode circuitry 108 and column decode circuitry 111 based on the memory addresses.

The cache register 118 latches data, either incoming or outgoing, as directed by the local media controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in the cache register 118 from the I/O control circuitry 112. During a read operation, data can be passed from the cache register 118 to the I/O control circuitry 112 for output to the memory sub-system controller 115; then new data can be passed from the data register 121 to the cache register 118. The cache register 118 and/or the data register 121 can form at least a portion of the page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to the memory sub-system controller 115.

The memory device 130 receives control signals at the memory sub-system controller 115 from the local media controller 135 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of the memory device 130. In some implementations, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an implementation, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

Additional circuitry and signals can be provided, as the diagram depicting the memory device 130 of FIG. 1B has been simplified. The functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various implementations.

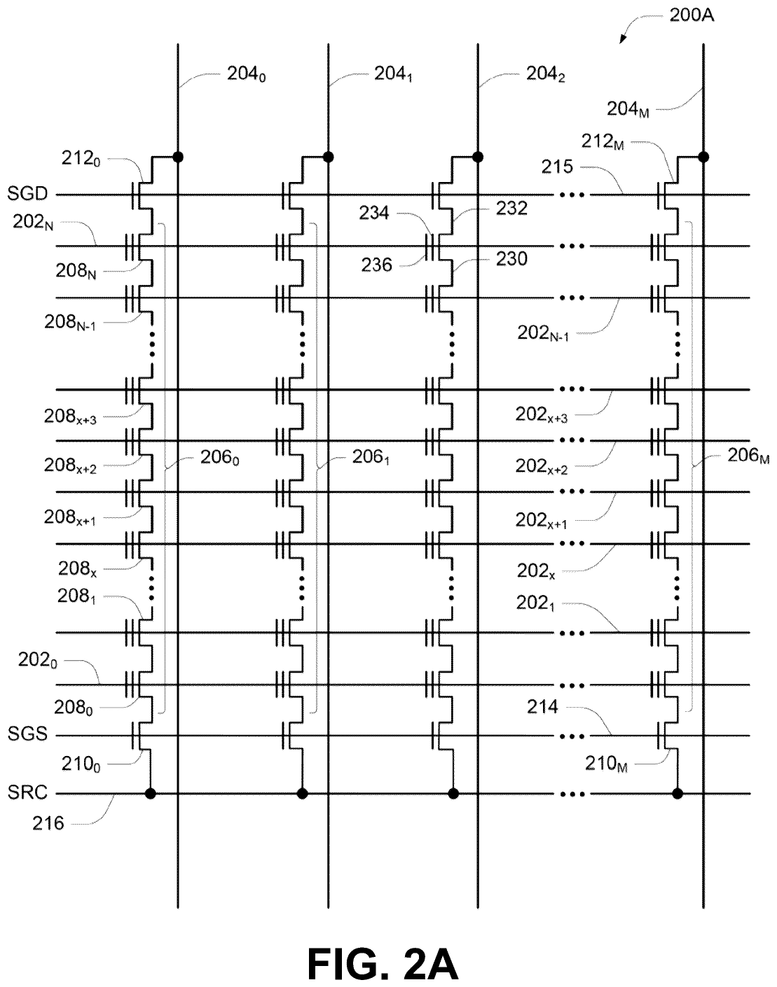

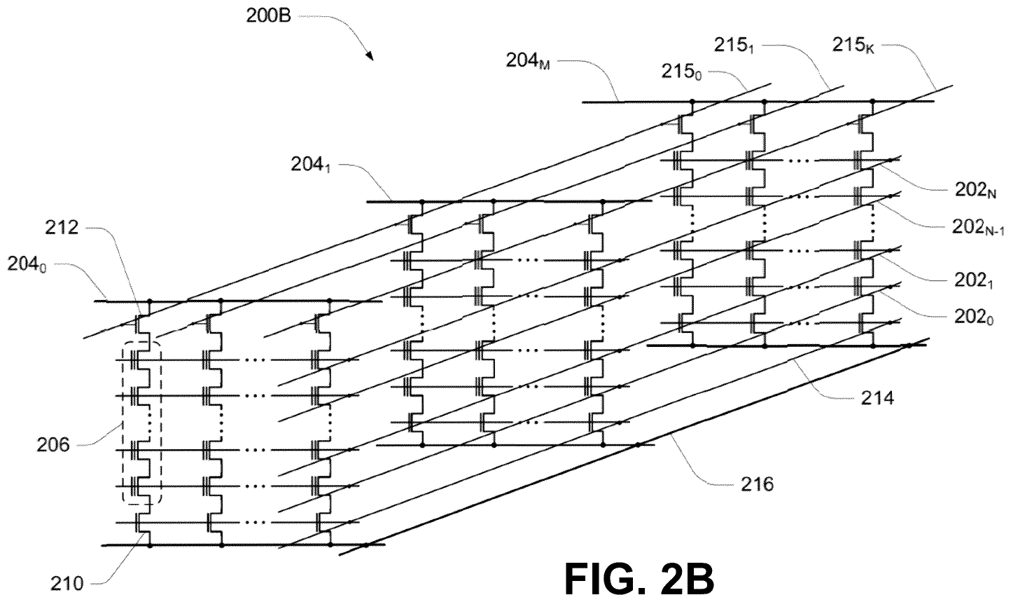

FIG. 2A-2B schematically illustrate portions of an array of memory cells 200A, such as a NAND memory array, as could be used in a memory of the type described with reference to FIG. 1B according to an implementation, e.g., as a portion of the array of memory cells 104. Memory array 200A includes access lines, such as wordlines 202₀ to 202_{N}, and data lines, such as bitlines 204₀ to 204_{M}. The wordlines 202 can be connected to global access lines (e.g., global wordlines), not shown in FIG. 2A, in a many-to-one relationship. For some implementations, memory array 200A can be formed over a semiconductor that, for example, can be conductively doped to have a conductivity type, such as a p-type conductivity, e.g., to form a p-well, or an n-type conductivity, e.g., to form an n-well.

Memory array 200A can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 2080 of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 200A in FIG. 2A can be a quasi-two-dimensional memory array and can have a generally planar structure, e.g., where the common source 216, NAND strings 206 and bitlines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2A, it is apparent from the figure that the bitlines 204 of the array of memory cells 200A can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some implementations, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2A is discussed in conjunction with NAND flash, the implementations and concepts described herein are not limited to a particular array architecture or structure, and can include other structures (e.g., SONOS, phase change, ferroelectric, etc.) and other architectures (e.g., AND arrays, NOR arrays, etc.).

FIG. 2B schematically illustrates a portion of an array of memory cells 200B as could be used in a memory of the type described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B can incorporate vertical structures which can include semiconductor pillars where a portion of a pillar can act as a channel region of the memory cells of NAND strings 206. The NAND strings 206 can be each selectively connected to a bitline 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bitline 204. Subsets of NAND strings 206 can be connected to their respective bitlines 204 by biasing the select lines 215₀-215_{K} to selectively activate particular select transistors 212 each between a NAND string 206 and a bitline 204. The select transistors 210 can be activated by biasing the select line 214. In some implementations, each sub-block or string of memory cells has a separate select line 214 from other sub-blocks or strings. In some implementations, a pair of sub-blocks shares a select line 214. Each wordline 202 can be connected to multiple rows of memory cells of the memory array 200B. Rows of memory cells that are commonly connected to each other by a particular wordline 202 can collectively be referred to as tiers.

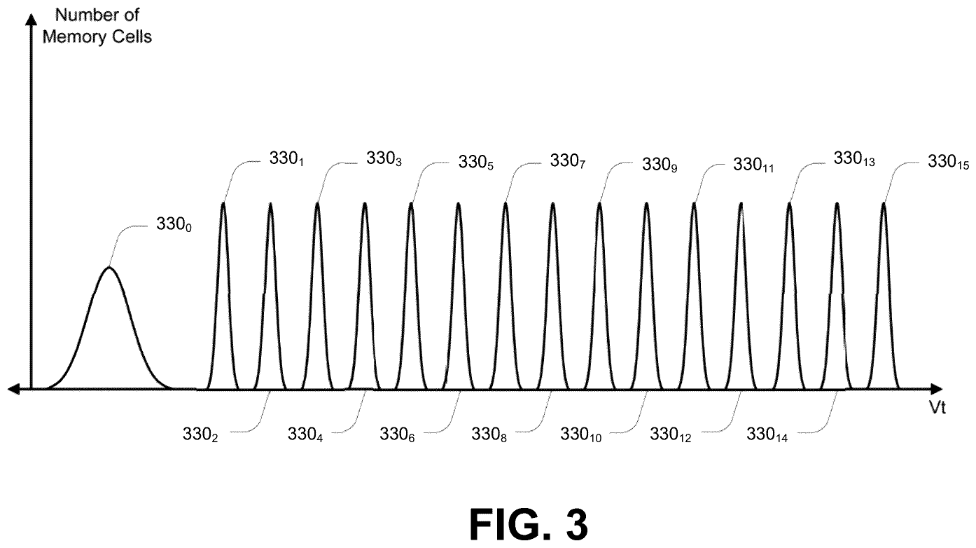

FIG. 3 is a conceptual depiction of threshold voltage ranges of multiple memory cells. FIG. 3 illustrates an example of threshold voltage ranges and their distributions for a population of a sixteen-level memory cells, e.g., QLC memory cells. For example, such a memory cell can be programmed to a threshold voltage (Vₜ) that falls within one of sixteen different threshold voltage ranges 330₀-330₁₅, each being used to represent a data state corresponding to a bit pattern of four bits. The threshold voltage range 330₀ typically has a greater width than the remaining threshold voltage ranges 330₁-330₁₅ as memory cells are generally all placed in the data state corresponding to the threshold voltage range 330₀, then subsets of those memory cells are subsequently programmed to have threshold voltages in one of the threshold voltage ranges 330₁-330₁₅. As programming operations are generally more incrementally controlled than erase operations, these threshold voltage ranges 330₁-330₁₅ can tend to have tighter distributions.

TABLE 1

| Data | Logical |
|---|---|
| State | Data Value |
| L0 | 1111 |
| L1 | 0111 |
| L2 | 0011 |
| L3 | 1011 |
| L4 | 1001 |
| L5 | 0001 |
| L6 | 0101 |
| L7 | 1101 |
| L8 | 1100 |
| L9 | 0100 |
| L10 | 0000 |
| L11 | 1000 |
| L12 | 1010 |
| L13 | 0010 |
| L14 | 0110 |
| L15 | 1110 |

The threshold voltage ranges 330₀, 330₁, 330₂, 330₃, 330₄, 330₅, 330₆, 330₇, 330₈, 330₉, 330₁₀, 330₁₁, 330₁₂, 330₁₃, 330₁₄, and 330₁₅ can each represent a respective data state, e.g., L0, L1, L2, L3, L4, L5, L6, L7, L8, L9, L10, L11, L12, L13, L14 and L15, respectively. As an example, if the threshold voltage of a memory cell is within the first of the sixteen threshold voltage ranges 330₀, the memory cell in this case can be storing a data state L0 having a data value of logical ‘1111’ and is typically referred to as the erased state of the memory cell. If the threshold voltage is within the second of the sixteen threshold voltage ranges 330₁, the memory cell in this case can be storing a data state L1 having a data value of logical ‘0111’. If the threshold voltage is within the third of the sixteen threshold voltage ranges 330₂, the memory cell in this case can be storing a data state L2 having a data value of logical ‘0011,’ and so on. Table 1 provides one possible correspondence between the data states and their corresponding logical data values. Other assignments of data states to logical data values are known or can be envisioned. Memory cells remaining in the lowest data state (e.g., the erased state or L0 data state), as used herein, will be deemed to be programmed to the lowest data state.

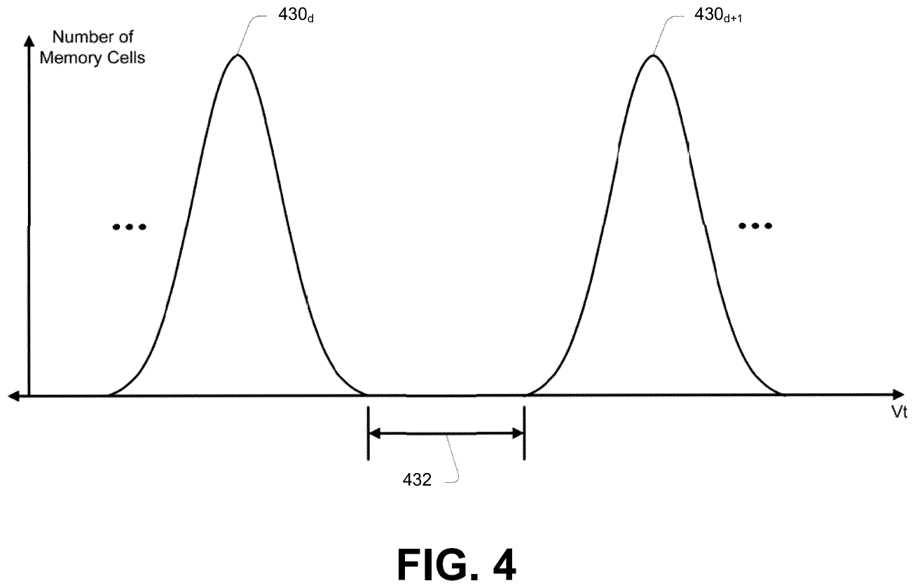

FIG. 4 schematically illustrates a threshold voltage distribution of multiple memory cells following a programming operation. The threshold voltage distributions 430_{d}-430_{d+1} of FIG. 4 can represent some portion of the distributions for threshold voltage ranges 330₀-330₁₅ of FIG. 3 at the completion of a programming operation for memory cells. With reference to FIG. 4, adjacent threshold voltage distributions 430 are typically separated by some margin 432 (e.g., dead space) at the completion of programming. Applying a sense voltage (e.g., read level voltage) within the margin 432 to the control gates of the multiple memory cells can be used to distinguish between the memory cells of the threshold voltage distribution 430_{d} (and any lower threshold voltage distribution) and the memory cells of the threshold voltage distribution 430_{d+1} (and any higher threshold voltage distribution).

Due to the phenomenon known as slow charge loss, the threshold voltage of a memory cell changes in time as the electric charge of the cell is degrading, which is referred to as “temporal voltage shift” (since the degrading electric charge causes the voltage distributions to shift along the voltage axis towards lower voltage levels). The threshold voltage is changing rapidly at first (immediately after the memory cell was programmed), and then slows down in an approximately logarithmic linear fashion with respect to the time elapsed since the cell programming event. This temporal voltage shift, if left unadjusted, reduces the margin 432 between the threshold voltage distributions 430_{d}-430_{d}+₁ over time, and can cause these threshold voltage distributions to overlap, thus making it more difficult to distinguish between adjacent threshold voltage distributions. Accordingly, failure to mitigate the temporal voltage shift caused by the slow charge loss can result in the increased bit error rate in read operations, which the fast read calibration described herein is intended to mitigate.

As noted herein above, the memory sub-system may employ a soft-decision decoding techniques, which may take into account “soft” input information (alongside a hard input value) indicating the reliability of a hard value determination (e.g., a confidence level or likelihood that a particular bit-value is in fact ‘0’ or ‘1’). Thus, a memory sub-system, in retrieving a stored codeword, may perform a read operation that not only returns a hard value as a series of hard bits, but also a series of one or more “soft bits” for each hard bit, which may indicate a reliability of a particular hard bit determination.

In an illustrative example, the controller may perform a read operation returning one “hard” bit and one “soft” bit of information (1H1S), which would involve three read strobes: a strobe at the base read level to produce the “hard” bit,” and two strobes with small negative and positive offsets applied to the read level, to produce the “soft” bit. The offsets are selected in such a way that the respective read levels produced by applying the offsets to the base read level would fall within the intersection of the two neighboring voltage distributions. Evidently, performing three read strobes in course of a single read operation results in tripling the latency of the read operation.

In order to reduce the read operation latency, in some implementations, the controller may perform a read operation returning one “hard” bit and ½ “soft” bit of information (1H0.5S), which would involve two read strobes: one strobe at the base read level to produce the “hard” bit,” and another strobe with a small negative or positive offset applied to the read level, to produce the ½ bit of “soft” information.

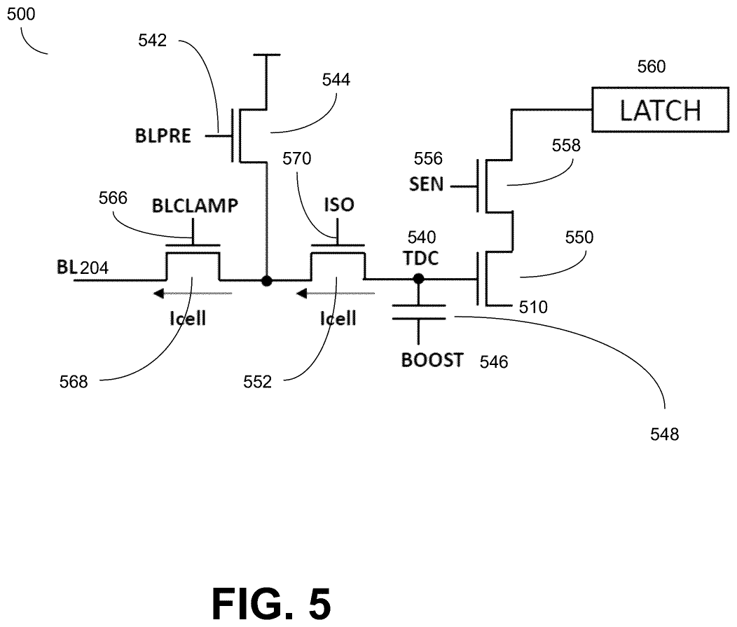

FIG. 5 schematically illustrates a simplified component diagram of a sense circuit 500 operating in accordance with some aspects of the present disclosure. In some implementations, the sense circuit 500 is, or is a part of, the page buffer 152 of FIGS. 1A-1B. The sense circuit 500 can perform a read operation on a target cell in the memory device. The sense circuit 500 can be connected, by the bitline 204, to a NAND string 206 (not shown in FIG. 5). Also omitted from FIG. 5 are the select gate transistors 210 and 212, which selectively connect the NAND string 206 to the source 216 and bitline 204, respectively, as schematically illustrated by FIGS. 2A-2B. While the below description is directed to use of the sense circuit 500 with a NAND string 206, other memory structures and architectures can be suitable for use with sense circuit 500 where a current path can be selectively created from the bitline 204 to the source 216 dependent upon the state of the target cell selected for sensing.

Various control signals of the sense circuit 500 can be provided by the internal controller (e.g., the local media controller 135) of the memory device 130. Such control signals (e.g., voltage levels and timing) can be defined by the read strobe parameters and are distinguished from signals generated in response to performing the read strobe (e.g., the output signal on the output line 510).

As part of the read strobe, the sense circuit 500 can boost (e.g., pre-charge) the sense node 540 by activating the boost transistor 544. The boost transistor 544 can be activated by driving the gate current 542 to the bitline precharge (BLPRE) level.

A sensing capacitor 548 coupled with the sense node 540 can provide the capacitance at the sense node 540. A voltage node (not shown in FIG. 5) can supply the boost voltage 546 to the capacitor 548, thus boosting the voltage level in the sense node 540 to a higher voltage level through the capacitive coupling. The boost voltage 546 may be provided by the boost voltage modulation circuitry (not shown in FIG. 5), which may include multiple boost regulators connected to a multiplexer. A selection line of the multiplexer can be controlled by the local media controller 135 for selectively adjusting the charge of the capacitor 548 in order to perform the read operations.

The charged sensing node 540 can discharge if the current is flowing through the sensing path that is implemented by the select transistor 558 and sense transistor 550. The select transistor 558 has its gate coupled to the sense signal line 556, its drain coupled to the latch 560, and its source coupled to the sense transistor 550. The sense transistor 550 has its gate coupled to the sense node 540, its drain coupled to the source of the select transistor 558, and its source coupled to the ground (not shown in FIG. 5). Thus, the sense transistor 550 operates depending upon the voltage level present on the sense node 540. The output line 510 of the first sensing path can be connected to the source of the first sense transistor 550. The sense signal line 556 can receive a control signal (“SEN”) that determines whether the sense transistor 550 is connected to the latch 560.

The trip point of the sensing path, which depends upon the threshold voltage (V_{T}) of the sense transistor 550, is a particular voltage level on the sense node 540 at which the sensing path outputs a first logical level indicative of a first state of the of the sensed target cell (e.g., when the voltage level of the sense node 540 is equal to or above the trip point). Conversely, if the voltage level of the sense node 540 is below the trip point, the sense circuit 500 can output a second logical level indicative of a second state of the sensed target cell.

As noted herein above, the sense circuit output line 510 can be connected to additional circuitry (not shown in FIG. 5) of the memory device 130 employed to respond to the sense circuit 500 as part of a read operation. For example, the sense circuit 500 can be a component of the data register 170 of FIG. 1B and its output 510 can be fed as an input to the cache register 118 for output of the sensed data state from the memory device 130. The output signal 510 can reflect the logical level indicative of the state of the of the selected memory cell of NAND string 206, which may be stored by the latch 560.

Thus, a read strobe can include charging the sensing capacitor 548, which then, depending on the state of the target memory cell, may cause the discharge current I_{cell} to flow to the bitline 204.

The precharge phase can be triggered by activating the transistor 552 by applying a predefined voltage level to the ISO signal line 570. During the precharge phase, the boost transistor 544 can be activated by driving the gate current 542 to the BLPRE level, thus injecting the boost current into the sense node 540.

Following the boosting of the sense node 540, the second phase of the read strobe can be performed to discharge the sense node 540, thus determining state of the of the selected memory cell of NAND string 206. In some implementations, following the boosting of the sense node 540, the sense node 540 can be isolated from the bitline 204, e.g., by deactivating the transistor 568 and/or the transistor 552.

The bitline 204 can then be selectively connected to the source line 216 (not shown in FIG. 5) depending upon whether the target cell selected for sensing is activated or deactivated in response to boosting the sense node 540. If a current is flowing through the NAND string 206 after discharging the bitline 204, the sense node 540 can again be connected to the bitline 204 by activating the transistors 552 and 568. The transistor 568 can be activated by applying a predefined voltage level to the BLCLAMP signal line 566. Activating transistors 544, 552, and 568 can connect the bitline 204 to the boost voltage 546, thus boosting the sense node 540.

The voltage level of the bitline 204 may be lower than the boost voltage level due to current flow through the NAND string 206. In such cases, the voltage level of the sense node 540 will likewise experience a drop. If the voltage level of the bitline 204 remains at the boosted voltage level, such as when the target cell selected for sensing remains deactivated, the voltage level of the sense node 540 can remain at its boosted voltage level. With the transistors 558 and 568 activated and the voltage level of the sense node 540 applied to the control gate of the sense transistor 550, the latch 560 can be selectively connected to the sense output line 510 depending on the voltage level of the sense node 540.

In some implementations, and as shown in FIG. 5, the select transistor 558, the sense transistor 550, and/or other transistors shown in FIG. 5 are n-channel metal oxide semiconductor (NMOS) transistors (e.g., nFETs). Alternatively, the select transistor 558, the sense transistor 550,, and/or other transistors shown in FIG. 5 are p-channel metal oxide semiconductor (PMOS) transistors (e.g., pFETs), in which case the “source” and “drain” designation in the above description should be swapped.

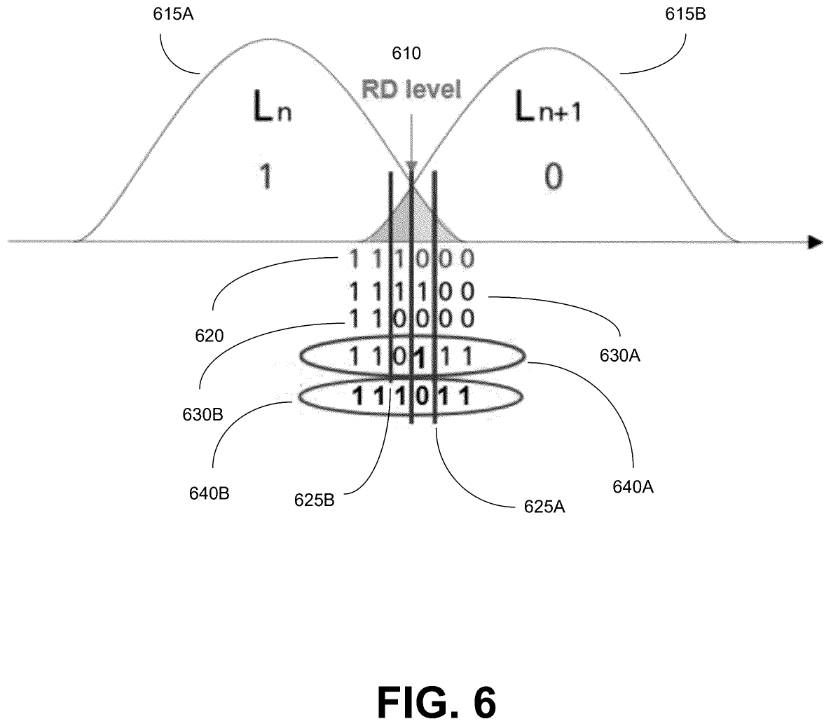

During the read operation, depending upon the position of the target cell relative to the V, distribution, which is determined by comparing the discharge current (I_{cell}) to the read level, the boost level may be adjusted either upwards or downwards in order to perform a second read strobe for capturing the corresponding ½ “soft” bit of information, as schematically illustrated by FIG. 6.

As shown in FIG. 6, assuming that the chosen read level 610 is situated between the maxima of the two neighboring V, distributions 615A and 615B, the “hard” information 620 (“111000”) can be returned by the read strobe at the read level 610. Conversely, the read strobe at the read level 625A, which has a positive offset applied to the read level 610, can return the information 630A. Similarly, the read strobe at the read level 625B, which has a negative offset applied to the read level 610, can return the information 630B. Accordingly, the respective “soft” information 640A-640B can be computed by applying the negative exclusive disjunction (XNOR) operation to the “hard” information 620 returned by the read strobe at the chosen read level 610 and corresponding information 630A-630B returned by the read strobes at the offset read levels 625A-625B. The combination of the “hard” information 620 and respective “soft” information 640A-640B may be converted into a likelihood value, which reflects the probability that the memory cell will be decoded as a specific binary value (e.g., “1”). In other words, the combination of the hard bit and one or more corresponding soft bits may be translated into a likelihood value (e.g., the LLR) that reflects the probability of the memory cell (having its threshold voltage within a decoder input bin that is identified by the combination of the hard bit and the corresponding soft bits) to be decoded as a particular binary value (e.g., “1”).

In some implementations, converting the combination of the hard bit and the soft bits into a corresponding likelihood (e.g., the log likelihood ratio (LLR)) value may be performed using a look-up table (LUT), which may map various possible combinations of the hard bit and soft bits into corresponding LLR values. The LUT may be pre-computed by the manufacturer of the memory sub-system and stored in the metadata area of a memory device. The memory sub-system may then provide the LLR values corresponding to the sensed data returned by a read operation to an LDPC decoder, which may attempt to decode the sensed data.

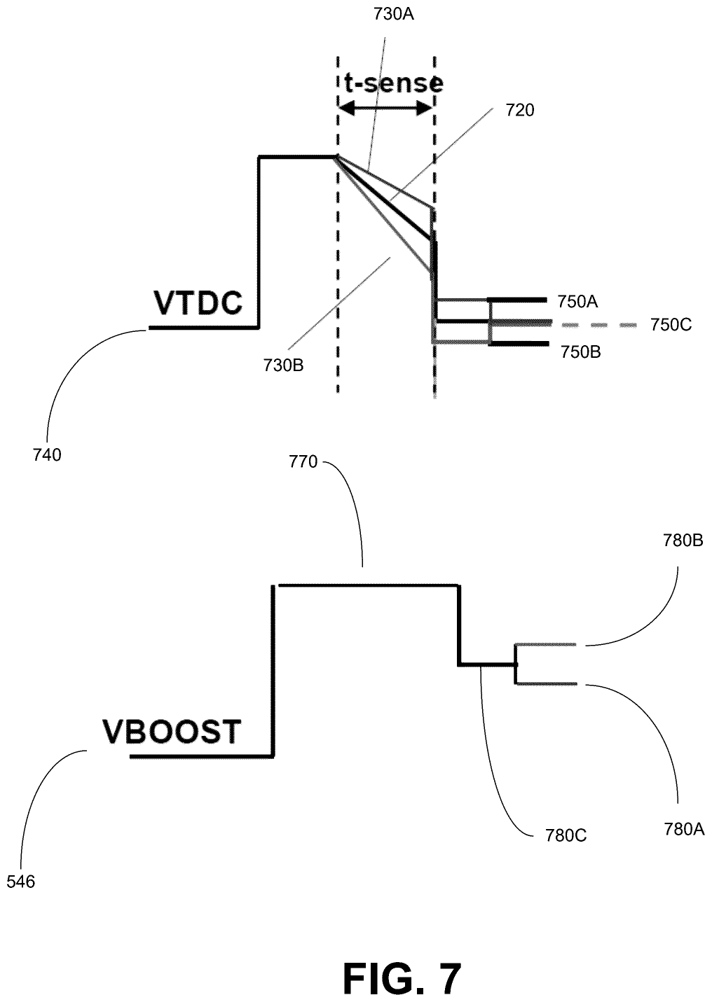

FIG. 7 schematically illustrates a set of graphs illustrating the boost modulation for performing a read operation, in accordance with aspects of the present disclosure. The sensing circuit 500 can precharge the sensing capacitor 548 such that the boost voltage 546 provided to the back plate of the sensing capacitor 548 can cause a shift in the reference sensing current of one or more memory cells. The boost voltage 546 can be modulated in order to cause a corresponding change in the voltage of the sense node (V_{tdc}) 740.

In some implementations, the sense node voltage (V_{tdc}) 740 may be discharged by the cell current during the development phase 770. The controller can adjust the boost voltage (V_{boost}) depending on the target sensing level. For the low target sensing level 730B, the discharge current (I_{cell}) should be higher so that the boost voltage (V_{boost}) is higher during the low target sensing strobe (V_{boost} value 780B corresponding to the V_{tdc} value 750B). Conversely, for the high target sensing level 730A, the sensing cell current (I_{cell}) should be lower so that the boost voltage (V_{boost}) is lower during the high target sensing strobe (V_{boost} value 780A corresponding to the V_{tdc} value 750A).

During the read operation, depending upon the position of the target cell relative to the corresponding V, distribution, which is determined by comparing the discharge (I_{cell}) current to the read level, the boost level may be adjusted either upwards or downwards in order to perform a second read strobe for capturing the corresponding ½ “soft” bit of information. Accordingly, responsive to performing the strobe at the target read level 750C (corresponding to the V_{boost} value 780C), thus acquiring the “hard” bit of information, the controller may proceed to acquire the ½ bits of “soft” information, by performing the strobe at either the high target level 750A (corresponding to the V_{boost} value 780A) or the low target level 750B (corresponding to the V_{boost} value 780B).

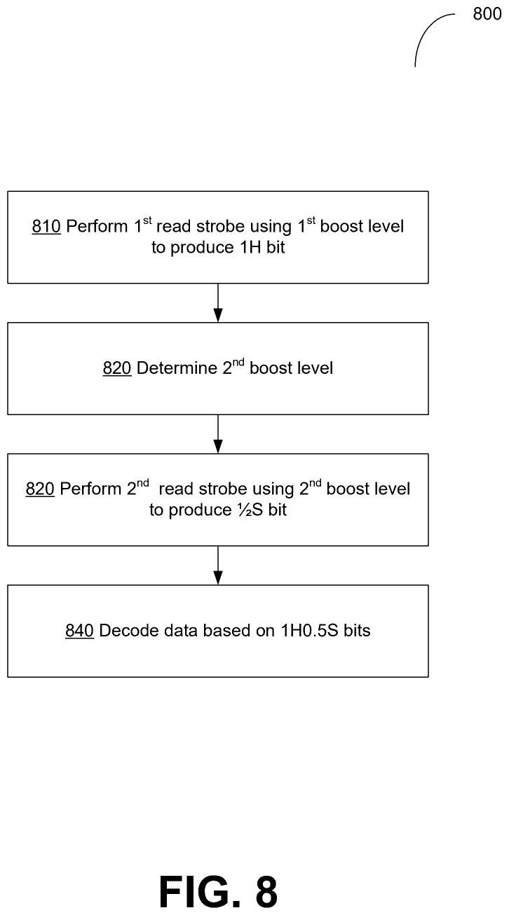

FIG. 8 is a high-level flow diagram of an example method 800 of performing a read operation with boost modulation in a memory device, in accordance with aspects of the present disclosure. The method 800 can be performed by processing logic that can include hardware (e.g., general purpose or specialized processing devices, circuitry, dedicated logic, programmable logic, microcode, integrated circuits, etc.), software (e.g., instructions run or executed on a processing device), or various combinations thereof. In some implementations, method 800 can be performed by a single processing thread. Alternatively, method 800 can be performed by two or more processing threads, each thread executing one or more individual functions, routines, subroutines, or operations of the method. In an illustrative example, the processing threads implementing method 800 can be synchronized (e.g., using semaphores, critical sections, and/or other thread synchronization mechanisms). Alternatively, the processing threads implementing method 800 can be executed asynchronously with respect to each other. In some implementations, the method 800 is performed by the memory system controller (e.g., memory access manager 134 of FIG. 1) and/or local media controller. Operations of method 800 can be specified by a sequence of command codes, which the processing logic can retrieve from a dedicated storage location. Although shown in a particular sequence or order, unless otherwise specified, the order of the operations can be modified. Thus, the illustrated implementations should be understood only as examples, and the illustrated operations can be performed in a different order, and some operations can be performed in parallel. Additionally, one or more operations can be omitted in various implementations. Thus, not all operations are required in every implementation.

At operation 810, the processing logic produces a first data item by performing, using a first boost voltage level, a first read strobe with respect to a set of memory cells (e.g., a memory page addressable by a selected wordline) that stores encoded data. In an illustrative example, the first data item includes one bit of “hard” information for each memory cell of the set of memory cells, as described in more detail herein above.

At operation 820, the processing logic produces a second boost voltage level by applying an offset to the first boost voltage level. The offset may be determined based on the discharge current flowing through the sensing circuit. The sign of the offset (negative or positive) depends on the position of the target cell relative to the V, distribution, which is determined by comparing the discharge current (I_{cell}) to the read voltage level, as described in more detail herein above.

At operation 830, the processing logic produces a second data item by performing, using the second boost voltage level, a second read strobe with respect to the set of memory cells. In an illustrative example, the second data item includes ½ bit of “soft” information for each memory cell of the set of memory cells, as described in more detail herein above.

At operation 840, the processing logic produces, based on the first data item and the second data item, decoded data corresponding to the encoded data stored by the plurality of memory cells. In an illustrative example, the processing logic determines, based on the first data item and the second data item, a likelihood value reflecting a probability of decoding each memory cell as a particular binary value. The likelihood values may then be fed to an LDPC decoder that performs the decoding operation using a low-density parity-check (LDPC) matrix, as described in more detail herein above.

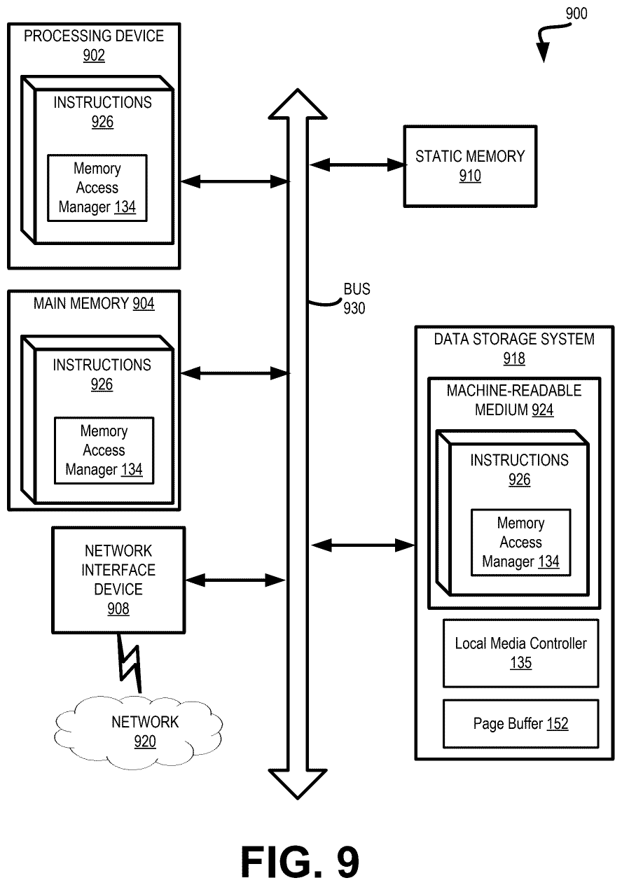

FIG. 9 illustrates an example machine of a computer system 900 within which a set of instructions, for causing the machine to perform any one or more of the methodologies discussed herein, can be executed. In some implementations, the computer system 900 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the memory sub-system controller 115 of FIG. 1A). In alternative implementations, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random access memory (DRAM) such as synchronous DRAM (SDRAM) or Rambus DRAM (RDRAM), etc.), a static memory 910 (e.g., flash memory, static random access memory (SRAM), etc.), and a data storage system 918, which communicate with each other via a bus 930.

Processing device 902 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 can also be one or more special-purpose processing devices such as an application specific integrated circuit (ASIC), a field programmable gate array (FPGA), a digital signal processor (DSP), network processor, or the like. The processing device 902 is configured to execute instructions 928 for performing the operations and steps discussed herein. The computer system 900 can further include a network interface device 908 to communicate over the network 920.

The data storage system 918 can include a machine-readable storage medium 924 (also known as a non-transitory computer-readable storage medium) on which is stored one or more sets of instructions 926 or software implementing the methods or functions described herein, including those associated with the memory access manager 134. The data storage system 918 can further include the local media controller 135 and the page buffer 152 that were previously discussed. The instructions 928 can also reside, completely or at least partially, within the main memory 904 and/or within the processing device 902 during execution thereof by the computer system 900, the main memory 904 and the processing device 902 also constituting machine-readable storage media. The machine-readable storage medium 924, data storage system 918, and/or main memory 904 can correspond to the memory sub-system 110 of FIG. 1A.

In some implementations, the instructions 926 include instructions to implement functionality corresponding to a controller (e.g., the memory sub-system controller 115 of FIG. 1A). While the machine-readable storage medium 924 is shown in an example implementation to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, implementations of the disclosure have been described with reference to specific example implementations thereof. It will be evident that various modifications can be made thereto without departing from the broader spirit and scope of implementations of the disclosure as set forth in the following claims. The specification and drawings are, accordingly, to be regarded in an illustrative sense rather than a restrictive sense.

What is claimed is:

1. A system, comprising:
a memory device; and
a processing device operatively coupled to the memory device, the processing device configured to:
produce a first data item by performing, using a first boost voltage level, a first read strobe with respect to a set of memory cells storing encoded data item;
apply an offset to the first boost voltage level to produce a second boost voltage level;
produce a second data item by performing, using the second boost voltage level, a second read strobe with respect to the set of memory cells; and
produce, based on the first data item and the second data item, decoded data item corresponding to the encoded data item.

2. The system of claim 1, wherein the first data item comprises one bit of hard information for each memory cell of the set of memory cells.

3. The system of claim 1, wherein the second data item comprises ½ bit of soft information for each memory cell of the set of memory cells.

4. The system of claim 1, wherein the offset is determined based on a discharge current flowing through a sensing circuit controlled by the processing device.

5. The system of claim 1, wherein the offset is provided by one of: a positive offset or a negative offset.

6. The system of claim 1, wherein producing the decoded data item further comprises:
determining, based on the first data item and the second data item, a likelihood value reflecting a probability of decoding a memory cell as a particular binary value.

7. The system of claim 1, wherein producing the decoded data item is performed using a low-density parity-check (LDPC) matrix.

8. A method, comprising:
producing, by a processing device, a first data item by performing, using a first boost voltage level, a first read strobe with respect to a set of memory cells storing encoded data item;
applying an offset to the first boost voltage level to produce a second boost voltage level;
producing a second data item by performing, using the second boost voltage level, a second read strobe with respect to the set of memory cells; and
producing, based on the first data item and the second data item, decoded data item corresponding to the encoded data item.

9. The method of claim 8, wherein the first data item comprises one bit of hard information for each memory cell of the set of memory cells.

10. The method of claim 8, wherein the second data item comprises ½ bit of soft information for each memory cell of the set of memory cells.

11. The method of claim 8, wherein the offset is determined based on a discharge current flowing through a sensing circuit controlled by the processing device.

12. The method of claim 8, wherein the offset is provided by one of: a positive offset or a negative offset.

13. The method of claim 8, wherein producing the decoded data item further comprises:
determining, based on the first data item and the second data item, a likelihood value reflecting a probability of decoding a memory cell as a particular binary value.

14. A non-transitory computer-readable storage medium comprising instructions that, when executed by a controller managing a memory device, cause the controller to:
produce a first data item by performing, using a first boost voltage level, a first read strobe with respect to a set of memory cells storing encoded data item;
apply an offset to the first boost voltage level to produce a second boost voltage level;
produce a second data item by performing, using the second boost voltage level, a second read strobe with respect to the set of memory cells; and
produce, based on the first data item and the second data item, decoded data item corresponding to the encoded data item.

15. The non-transitory computer-readable storage medium of claim 14, wherein the first data item comprises one bit of hard information for each memory cell of the set of memory cells.

16. The non-transitory computer-readable storage medium of claim 14, wherein the second data item comprises ½ bit of soft information for each memory cell of the set of memory cells.

17. The non-transitory computer-readable storage medium of claim 14, wherein the offset is determined based on a discharge current flowing through a sensing circuit controlled by the processing device.

18. The non-transitory computer-readable storage medium of claim 14, wherein the offset is provided by one of: a positive offset or a negative offset.

19. The non-transitory computer-readable storage medium of claim 14, wherein producing the decoded data item further comprises:
determining, based on the first data item and the second data item, a likelihood value reflecting a probability of decoding a memory cell as a particular binary value.

20. The non-transitory computer-readable storage medium of claim 14, wherein producing the decoded data item is performed using a low-density parity-check (LDPC) matrix.
